(19) United States
(12) Patent Application Publication
(10) Pub. No.: US 2026/0361294 A1
(43) Pub. Date: Nov. 12, 2026

(54) SIGNAL CORRECTION SYSTEM AND SIGNAL CORRECTION METHOD

(71) Applicant: Nuvoton Technology Corporation, Hsinchu Science Park (TW)

(72) Inventors: Chih-Ming CHEN, Jhuangwei Township (TW); Fu-Sheng HSU, Tainan City (TW)

(21) Appl. No.: 19/639,552

(22) Filed: Apr. 6, 2026

(30) Foreign Application Priority Data
May 8, 2025 (TW) 114117312

(51) Int. Cl. H03K 3/011; H03K 3/0231; H04L 25/06

(52) U.S. Cl. CPC H03K 3/011; H03K 3/0231; H04L 25/06

(57) ABSTRACT

A signal correction system includes a trim value adjuster, a comparator group, a digital signal processor, and a processor. The processor is configured to output a first result signal by a learning algorithm according to a first detection signal, first impedance data, and first packet feedback data. The trim value adjuster outputs a first trim signal according to the first result signal. The comparator group outputs a first slice signal according to a first reference signal and the first trim signal. The digital signal processor outputs second packet feedback data according to the first slice signal. The processor outputs a second result signal to the trim value adjuster by using the learning algorithm according to the second packet feedback data.

### CROSS REFERENCE TO RELATED APPLICATIONS

This application claims priority of TW patent application No. 114117312, filed on May 8, 2025, the entirety of which is incorporated by reference herein.

### BACKGROUND OF THE INVENTION

### Field of the Invention

The present invention relates to a correction system and correction method, and, in particular, it is related to a signal correction system and signal correction method.

### Description of the Related Art

Currently, automatic charging devices are used widely. The USB Power Delivery (USB PD) specification is currently the most commonly used charging and data transmission standard.

However, during the charging process, an automatic charging device may experience a voltage lift on the ground line due to the impedance effects of transmission cables and printed circuit boards (PCB). This phenomenon is related to the magnitude of the current being drawn.

In actual operation, as the charging current increases, the voltage lifting phenomenon on the ground line may become more pronounced. Furthermore, when the voltage lifting level increases, the probability of data packet decoding errors will increase unless the (corresponding) processing circuitry at the receiving end does not perform timely adjustments.

Therefore, a signal correction system capable of stably adjusting signals and correctly receiving data packets is an urgently needed subject for research and development.

### BRIEF SUMMARY OF THE INVENTION

The Brief Summary of the Invention is intended to provide a simplified summary of the present disclosure to enable readers to have a basic understanding thereof. This summary is not an exhaustive overview of the present disclosure, and is not intended to identify key or critical elements of the embodiments of the present disclosure or to define the scope thereof.

An embodiment of the present invention provides a signal correction system. The signal correction system includes a trim value adjuster, a comparator group, a digital signal processor, and a processor. The comparator group is coupled to the trim value adjuster. The digital signal processor is coupled to the comparator group. The processor is coupled to the trim value adjuster. The processor is configured to output a first result signal by a learning algorithm according to a first detection signal, first impedance data, and first packet feedback data. The trim value adjuster outputs a first trim signal according to the first result signal. The comparator group outputs a first slice signal according to a first reference signal and the first trim signal. The digital signal processor outputs second packet feedback data according to the first slice signal. The processor outputs a second result signal to the trim value adjuster by using the learning algorithm according to the second packet feedback data.

In one embodiment, the trim value adjuster outputs a second trim signal according to the second result signal; wherein the comparator group outputs a second slice signal to the digital signal processor according to a first reference signal and the second trim signal; wherein a voltage level of the first slice signal is greater than or equal to a voltage level of the second slice signal.

In one embodiment, the signal correction system further includes a current detector. The current detector is configured to output the first detection signal according to a charging signal. Wherein the processor constructs a first data trend line according to a plurality of detection signals and a plurality of slice signals; wherein the processor updates the learning algorithm according to the first data trend line; wherein the plurality of detection signals include the first detection signal; wherein the plurality of slice signals include the first slice signal.

In one embodiment, the processor constructs a second data trend line according to a plurality of detection signals and a plurality of impedance data; wherein the processor updates the learning algorithm according to the second data trend line; wherein the plurality of impedance data include the first impedance data.

In one embodiment, the digital signal processor outputs a packet data, and the packet data includes a check interval, a packet end interval, and a trigger time point; wherein, at the trigger time point, the digital signal processor outputs the first packet feedback data to the processor; wherein the trigger time point is located after the check interval, and the packet end interval is located after the trigger time point.

In one embodiment, the signal correction system further includes a filter. The filter is configured to output a first waveform signal and a second waveform signal according to the first reference signal. Wherein a first wavelength width of the first waveform signal along a first axial direction is smaller than a second wavelength width of the second waveform signal along the first axial direction.

In one embodiment, the comparator group outputs a first slice waveform signal and a second slice waveform signal according to the first waveform signal, the second waveform signal, and the first trim signal; wherein the digital signal processor outputs a third packet feedback data according to the first slice waveform signal and/or the second slice waveform signal; wherein the processor outputs a third result signal to a trim value adjuster by using the learning algorithm according to the third packet feedback data.

In one embodiment, the processor obtains a first slope data according to the first slice waveform signal and the second slice waveform signal; wherein the processor updates the learning algorithm according to the first slope data.

In one embodiment, the processor obtains a first slice count data and a second slice count data respectively according to the first slice waveform signal and the second slice waveform signal; wherein the processor constructs a third data trend line according to a plurality of ground signals and a plurality of slice count data; wherein the processor updates the learning algorithm according to the third data trend line; wherein the plurality of slice count data includes the first slice waveform signal and the second slice waveform signal.

Other embodiment of the present invention provides a signal correction method. The signal correction method includes the following steps: outputting a first result signal by a learning algorithm according to a first detection signal, a first impedance data, and a first packet feedback data; outputting a first trim signal according to the first result signal; outputting a first slice signal according to a first reference signal and the first trim signal; outputting a second packet feedback data according to the first slice signal; outputting a second result signal by the learning algorithm according to the second packet feedback data; outputting a packet data according to the second result signal, wherein the packet data includes a check interval, a packet end interval and a trigger time point; and during the trigger time point, outputting a second packet feedback data to a processor.

In one embodiment, the signal correction method further includes the following steps: outputting the first detection signal according to a charging signal; constructing a first data trend line according to a plurality of detection signals and a plurality of slice signals; constructing a second data trend line according to a plurality of detection signals and a plurality of impedance data; and updating the learning algorithm according to the first data trend line and/or the second data trend line; wherein the plurality of detection signals includes the first detection signal, the plurality of slice signals includes the first slice signal, and the plurality of impedance data includes the first impedance data; wherein the first data trend line and the second data trend line are respectively associated with a voltage level of a ground line.

In one embodiment, the signal correction method further includes the following steps: outputting a first waveform signal and a second waveform signal according to the first reference signal; wherein a first wavelength width of the first waveform signal along a first axial direction is smaller than a second wavelength width of the second waveform signal along the first axial direction; wherein the first waveform signal and the second waveform signal are respectively associated with a baseboard management controller (BMC) signal.

In one embodiment, the signal correction method further includes the following steps: outputting a first slice waveform signal and a second slice waveform signal according to the first waveform signal, the second waveform signal, and the first trim signal; outputting a third packet feedback data according to the first slice waveform signal and/or the second slice waveform signal; and outputting a third result signal to a trim value adjuster by the learning algorithm according to the third packet feedback data; wherein the third packet feedback data includes one of a permitted packet feedback message and an error packet feedback message.

In one embodiment, the signal correction method further includes the following steps: obtaining a first slope data according to the first slice waveform signal and the second slice waveform signal; and updating the learning algorithm according to the first slope data; wherein the first slope data is associated to the first wavelength width and the second wavelength width.

In one embodiment, the signal correction method further includes the following steps: obtaining a first slice count data and a second slice count data respectively according to the first slice waveform signal and the second slice waveform signal; constructing a third data trend line according to a plurality of ground signals and a plurality of slice count data; and updating the learning algorithm according to the third data trend line; wherein the plurality of slice count data includes the first slice waveform signal and the second slice waveform signal; wherein the plurality of ground signals is associated to a voltage level of a ground line.

Therefore, according to the technical content of the present disclosure, the signal correction system and signal correction method shown in the embodiment of the present disclosure can achieve the effect of stably receiving correct packet data by continuously and dynamically adjusting trim values.

Other features and aspects of the present disclosure will become apparent from the following detailed description of exemplary embodiments with reference to the accompanying drawings.

After reviewing the embodiments described below, those having ordinary skill in the art will readily understand the basic spirit and other objectives of the present invention, as well as the technical means and implementation modes adopted by the present invention.

### BRIEF DESCRIPTION OF THE DRAWINGS

The views of the embodiments of the present disclosure can be better understood through the following detailed description combined with the accompanying drawings. It is worth noting that, according to standard industrial practice, some features may not be drawn to scale. In fact, to facilitate clear description, the dimensions of different features may be increased or decreased, wherein:

FIG. 1 is a block diagram of a signal correction system according to one embodiment of the present disclosure.

FIG. 2 is a block diagram of a charger of a signal correction system according to one embodiment of the present disclosure.

FIG. 3 is a block diagram of a comparator group of a signal correction system according to one embodiment of the present disclosure.

FIG. 4 is a diagram of a plurality of signal trends of a signal correction system according to one embodiment of the present disclosure.

FIG. 5 is a diagram of a plurality of signal trends of a signal correction system according to one embodiment of the present disclosure.

FIG. 6 is a diagram of a plurality of signal levels of a signal correction system according to one embodiment of the present disclosure.

FIG. 7 is a block diagram of a signal correction system according to one embodiment of the present disclosure.

FIG. 8 is a waveform diagram of a waveform signal of a signal correction system according to one embodiment of the present disclosure.

FIG. 9 is a waveform diagram of a plurality of signals of a signal correction system according to one embodiment of the present disclosure.

FIG. 10 is a diagram of a plurality of signal trends of a signal correction system according to one embodiment of the present disclosure.

FIG. 11 is a diagram of a plurality of signal trends of a signal correction system according to one embodiment of the present disclosure.

FIG. 12A is a flowchart of a signal correction method according to one embodiment of the present disclosure.

FIG. 12B is a flowchart of a signal correction method according to one embodiment of the present disclosure.

According to conventional practice, the various features and components illustrated in the drawings are depicted in a manner that best represents the specific features and components relevant to the present invention. In addition, in different figures, identical or similar reference numerals are used to denote identical or similar elements or components.

### DETAILED DESCRIPTION OF THE INVENTION

The following description is made for the purpose of illustrating the general principles of the invention and should not be taken in a limiting sense. The scope of the invention is best determined by reference to the appended claims.

The word “embodiment” as used herein means “serving as an example, example, or illustrative.” Any embodiment described herein as “embodiment” is not necessarily to be construed as superior or superior to other embodiments.

In addition, in order to better explain the present disclosure, numerous specific details are provided in the following specific embodiments. It will be understood by those skilled in the art that the present disclosure may be practiced without certain specific details. In some instances, methods, means, components and circuits that are well known to those skilled in the art are not described in detail in order to highlight the gist of the disclosure.

To make the description of the present disclosure more detailed and complete, illustrative descriptions are provided below for the implementation aspects and specific embodiments of the present case. However, this is not the sole form of implementing or utilizing the specific embodiments of the present case. The embodiments cover the features of multiple specific embodiments as well as the method steps and their sequence for constructing and operating these specific embodiments. Nevertheless, the same or equivalent functions and sequence of steps can also be achieved using other specific embodiments.

Unless otherwise defined in this specification, the meaning of scientific and technical terms used herein is the same as commonly understood and customary by a person having ordinary skill in the art to which the present case pertains. Furthermore, without conflicting with the context, singular nouns used in this specification cover their plural forms; and plural nouns also cover their singular forms.

In some embodiments of the present disclosure, terms related to joining and connecting, such as “connect,” “interconnect,” and “bond,” unless specifically defined otherwise, may refer to situations where two structures are in direct contact, or may also refer to situations where two structures are not in direct contact, with other structures arranged between these two structures. Moreover, these terms related to connecting and joining may also include cases where both structures are movable, or both structures are fixed. Additionally, “coupled” or “connected” as used herein may refer to two or more components being in direct physical or electrical contact with each other, or indirect physical or electrical contact with each other, and may also refer to two or more components interacting or operating with each other.

Some embodiments of the present disclosure can be understood in conjunction with the drawings, and the drawings of the embodiments of the present disclosure are also considered as part of the description of the embodiments of the present disclosure. It should be understood that the drawings of the embodiments of the present disclosure are not drawn to the actual scale of devices and components. The shapes and thicknesses of the embodiments may be exaggerated in the drawings to clearly illustrate the features of the embodiments of the present disclosure. Furthermore, the structures and devices in the drawings are schematically illustrated to clearly illustrate the features of the embodiments of the present disclosure.

Herein, the term “apparatus” generally refers to an object connected in a certain way to process signals, composed of one or more transistors and/or one or more active/passive components.

Here, the terms “about,” “approximately,” and “roughly” generally indicate within 20% of a given value or range, preferably within 10%, and more preferably within 5%, or within 3%, or within 2%, or within 1%, or within 0.5%. The quantities given herein are approximate quantities, meaning that the meaning of “about,” “approximately,” or “roughly” may still be implicitly included even without specific mention of “about,” “approximately,” or “roughly”. The term “a range between a first value and a second value” means that the described range includes the first value, the second value, and other values between them. Furthermore, a certain error may exist between any two values or directions used for comparison. If the first value is equal to the second value, it implies that there may be an error of about 10%, or within 5%, or within 3%, or within 2%, or within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms will be used throughout the entire specification and claims of the present disclosure to refer to specific components. A person having ordinary skill in the art should understand that electronic device manufacturers may refer to the same components by different names. This document is not intended to distinguish between components that have the same function but different names. In the following specification and claims, terms such as “comprising” “containing” and “having” are open-ended terms, and therefore they should be interpreted as “containing but not limited to . . . ”. Thus, when the terms “comprising” “containing” and/or “having” are used in the description of the present disclosure, they specify the presence of corresponding parts, regions, steps, operations, and/or elements, but do not exclude the presence of one or more corresponding parts, regions, steps, operations, and/or elements.

It should be understood that the components from multiple different embodiments can be substituted, rearranged, and combined to complete other embodiments without departing from the spirit of the present disclosure. Components between various embodiments can be arbitrarily combined and used together, as long as they do not violate the spirit of the invention or conflict with each other.

Unless otherwise defined, all terms used herein (including technical and scientific terms) have the same meaning as commonly understood by a person having ordinary skill in the art to which the present disclosure pertains. It can be understood that these terms, for example, terms defined in commonly used dictionaries, should be interpreted as having a meaning consistent with the relevant art and the background or context of the present disclosure, and should not be interpreted in an idealized or overly formal sense, unless specifically defined in the embodiments of the present disclosure.

In the present disclosure, various directions are not limited to the three axes like the X-axis, Y-axis, and Z-axis of a Cartesian coordinate system, and can be interpreted in a broader sense. For example, the X-axis, Y-axis, and Z-axis may be perpendicular to each other, or may represent different directions that are not perpendicular to each other, but are not limited thereto. For convenience of description, hereinafter, the X-axis direction is the first direction (width direction), the Y-axis direction is the second direction (length direction), and the Z-axis direction is the third direction (thickness or height direction). In some embodiments, the cross-sectional schematic view described herein is a cross-sectional schematic view observed in the XZ plane. In some embodiments, the third direction may be the normal direction of the substrate. In some embodiments, the third direction may be the front direction of the signal correction system.

In some embodiments, additional components may be added to the signal correction system of the present disclosure. In some embodiments, some components of the signal correction system of the present disclosure may be replaced or omitted. In some embodiments, additional operational steps may be provided before, during, and/or after the manufacturing method of the signal correction system. In some embodiments, some of the described operational steps may be replaced or omitted, and the sequence of some of the described operational steps is interchangeable. Furthermore, it should be understood that some of the described steps may be replaced or deleted for other embodiments of the method. Moreover, in the present disclosure, the number and size of each component in the drawings are for illustrative purposes only, and are not intended to limit the scope of the present disclosure.

First, in order to enable readers to quickly grasp the technical framework of the present disclosure, the detailed description of the invention first provides a general description of the respective structures of the signal correction system and the signal correction method, and subsequently provides more detailed explanations with reference to the accompanying drawings.

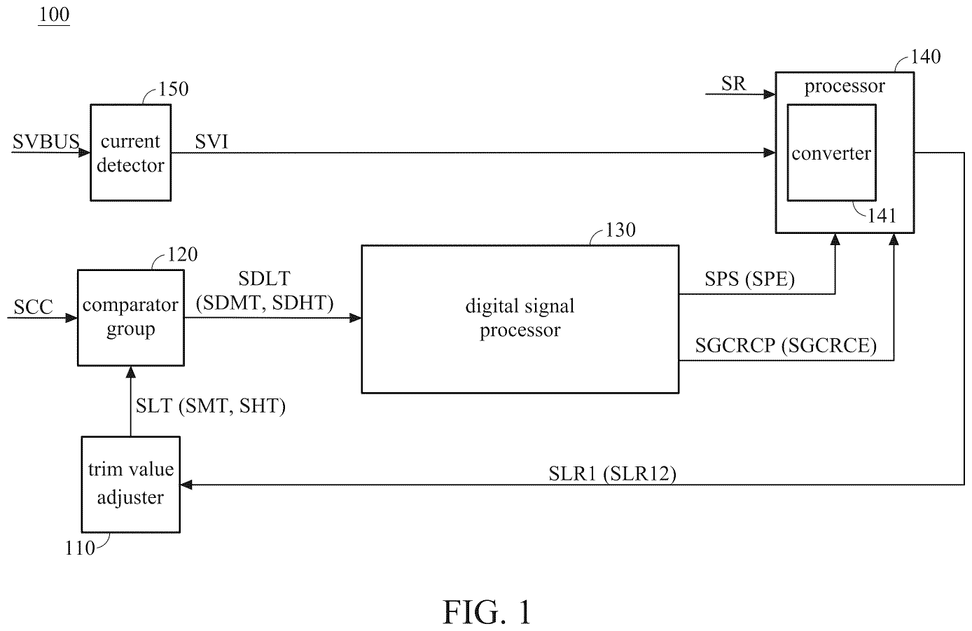

In one embodiment, as shown in the signal correction system 100 of FIG. 1, the signal correction system 100 may operate under various power delivery (PD) and charging environments. The processor 140 may utilize a machine learning (ML) algorithm to interpret, according to packet detection results, a current environment under a certain cable impedance, including ground voltage rise under different cable impedances and load current conditions. Accordingly, the processor 140 provides real-time adjustments to comparison reference voltage levels of analog circuits and generates a permitted packet feedback message (GoodCRC_PASS) as a normal response. The signal correction system 100 may continuously monitor packet information and generate packet response flags, such as a permitted packet feedback message (GoodCRC_PASS) or an error packet feedback message (GoodCRC_Error), to provide the system with analysis of the magnitude of ground current voltage drop.

The learning parameters of the machine learning (ML) algorithm of the processor 140 may be obtained during a system development stage through various practical operations, such as different impedance values and load current levels. Digital decoding of PD packets may be performed at a packet end. The processor 140 may, according to the obtained packet feedback message, such as a permitted packet feedback message (GoodCRC_PASS) or an error packet feedback message (GoodCRC_Error), use the packet feedback message as an important timing point for the ML algorithm to adjust analog parameter settings. At this time, it is also confirmed whether a packet start has been detected. The adjustment compensation (or offset) of analog comparators (such as the comparator group 120) may be designed according to a required analysis resolution.

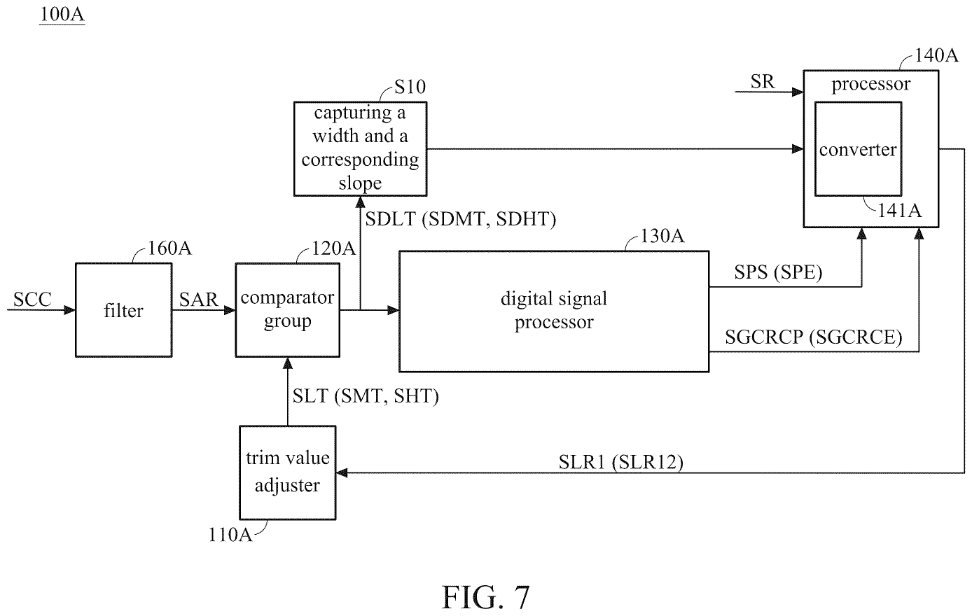

In one embodiment, as shown in the signal correction system 100A of FIG. 7, the signal correction system 100A may correspond to various charging load conditions, such as slice counts (slice counter) and corresponding wavelength widths, to establish related models. The signal correction system 100A may also correspond to various charging load conditions, such as slice counts and corresponding slopes, to establish related models. The learning parameters of the machine learning (ML) algorithm of the processor 140A may be obtained during the system development stage through various practical operations, such as impedance values and load current levels.

The signal correction system 100A may, according to packet detection result signals, interpret a current environment under a certain cable impedance. Under different cable impedances and load current conditions, the signal correction system 100A analyzes high-level and low-level widths and related slope relationships of outputs of three slice waveform signals as references for correction. When ground voltage rises, the signal correction system 100A may instantaneously adjust comparison reference voltage levels of analog circuits and generate a permitted packet feedback message (GoodCRC_PASS) as a normal response.

The signal correction system 100A may continuously monitor packet information and generate packet response flags, such as a permitted packet feedback message (GoodCRC_PASS) or an error packet feedback message (GoodCRC_Error), to provide the system with analysis of the magnitude of ground current voltage drop. Digital decoding of PD packets may be performed at a packet end. The processor 140A may, according to the obtained packet feedback message, such as a permitted packet feedback message (GoodCRC_PASS) or an error packet feedback message (GoodCRC_Error), use the packet feedback message as an important timing point for the machine learning (ML) algorithm to adjust analog parameter settings. At this time, it is also confirmed whether a packet start has been detected. The adjustment compensation (or offset) of analog comparators (such as the comparator group 120) may be designed according to a required analysis resolution.

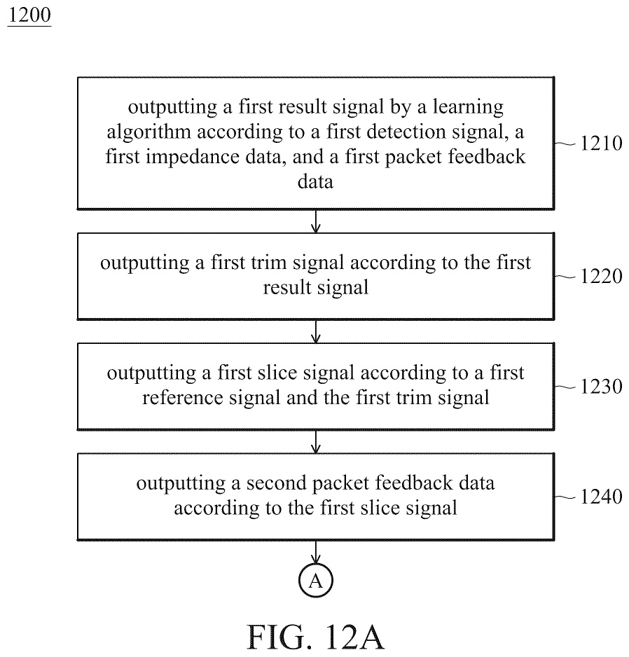

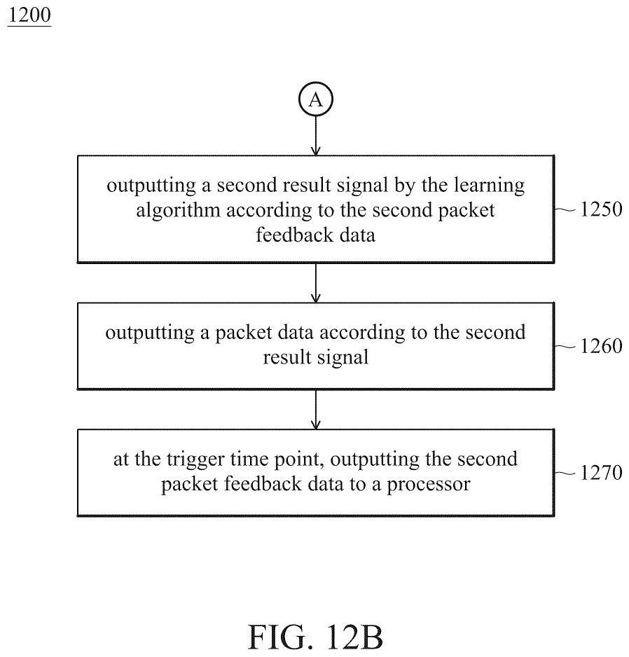

In one embodiment, as shown in the signal correction method 1200 of FIG. 12A and FIG. 12B, a plurality of operations of the signal correction method 1200 may correspond to the plurality of operations of the signal correction system 100 of FIG. 1 and achieve similar technical effects. For the sake of brevity, detailed descriptions thereof are not repeated herein. Furthermore, the following description will provide more detailed explanations with reference to the accompanying drawings.

FIG. 1 is a block diagram of a signal correction system according to one embodiment of the present disclosure. As shown in FIG. 1, in one embodiment, the signal correction system 100 includes the trim value adjuster 110, the comparator group 120, the digital signal processor 130, and the processor 140. The comparator group 120 is coupled to the trim value adjuster 110. The digital signal processor 130 is coupled to the comparator group 120. The processor 140 is coupled to the trim value adjuster 110.

For example, the processor 140 may execute a learning algorithm. The learning algorithm may be an artificial intelligence (AI) algorithm, an artificial neural network (ANN) algorithm, a machine learning (ML) algorithm, or a deep learning (DL) algorithm, but the present disclosure is not limited thereto.

In some embodiments, the digital signal processor 130 may be different from the processor 140, but the present disclosure is not limited thereto. In some embodiments, the digital signal processor 130 may be the same as the processor 140, but the present disclosure is not limited thereto. In some embodiments, the digital signal processor 130 may be disposed within the processor 140, but the present disclosure is not limited thereto.

In some embodiments, the processor 140 may be a microprocessor unit (MPU), a central processing unit (CPU), a graphics processing unit (GPU), a microcontroller unit (MCU), a server processor, or any other suitable processing unit, but the present disclosure is not limited thereto.

In one embodiment, the processor 140 outputs the first result signal SLR1by the learning algorithm according to first detection signal SVI, first impedance data SR [symbol] first packet feedback data SGCRCP.

For example, the first detection signal SVI may be a ground line voltage or current (floating) signal. The first impedance data SR may be an impedance value (also referred to as a resistance value) of a resistor. The first packet feedback data SGCRCP may be an error packet feedback message (GoodCRC_Error). The first result signal SLR1 may be a signal related to whether a trim value is to be adjusted, but the present disclosure is not limited thereto.

In addition, the first detection signal SVI may correspond to the ground line signal SR2 of the ground line in the current detector 150A. The first impedance data SR may be a sum of the resistance values of a plurality of resistors RCT3, RCGD, and RCT4 in the current detector 150A, but the present disclosure is not limited thereto.

In some embodiments, digital signal processor 130 may output a packet start signal SPS and a packet end signal SPE to the processor 140, but the present disclosure is not limited thereto. In some embodiments, the processor 140 may train and update the learning algorithm according to the first detection signal SVI, the first impedance data SR, the first packet feedback data SGCRCP, the packet start signal SPS, and the packet end signal SPE, but the present disclosure is not limited thereto. In one embodiment, the processor 140 may include a converter 141, and the converter 141 may be a ground IR drop converter, but the present disclosure is not limited thereto.

In one embodiment, the trim value adjuster 110 outputs a first trim signal SLT according to the first result signal SLR1.

For example, the trim value adjuster 110 may be any electronic component used to adjust a trim value. The first trim signal SLT, SMT, or SHT may be a slice trim value (such as the slice_L trim value), but the present disclosure is not limited thereto.

In some embodiments, the trim signal SLT, SMT, or SHT may be the slice trim value (such as the slice_L/M/H trim value), but the present disclosure is not limited thereto. In some embodiments, trim signal SLT may be the slice trim value (such as the slice_L trim value), but the present disclosure is not limited thereto. In some embodiments, the trim signal SMT may be the slice trim value (such as the slice_M trim value), but the present disclosure is not limited thereto. In some embodiments, the trim signal SHT may be the slice trim value (such as the slice_H trim value), but the present disclosure is not limited thereto.

In one embodiment, the comparator group 120 outputs a first slice signal SDLT according to the first reference signal SCC and the first trim signal SLT.

For example, the comparator group 120 may include at least one comparator. The first reference signal SCC may be a signal from an output terminal (such as the CC pin). The first slice signals SDLT, SDMT, or SDHT may be a result of digitizing the first reference signal SCC according to the first trim signal SLT (such as a CC digital signal), and the first slice signal SDLT may be represented as slice_1[2:0], but the present disclosure is not limited thereto.

In one embodiment, the digital signal processor 130 outputs second packet feedback data SGCRCE according to first slice signal SDLT.

For example, the first packet feedback data SGCRCP may be the permitted packet feedback message (GoodCRC_PASS), but the present disclosure is not limited thereto.

In some embodiments, the first packet feedback data SGCRCP may be the permitted packet feedback message (GoodCRC_PASS) or the error packet feedback message (GoodCRC_Error). The second packet feedback data SGCRCE may be the permitted packet feedback message (GoodCRC_PASS) or the error packet feedback message (GoodCRC_Error), but the present disclosure is not limited thereto.

In one embodiment, the processor 140 outputs the second result signal SLR12 to the trim value adjuster 110 by the learning algorithm according to second packet feedback data SGCRCE.

For example, the second result signal SLR12 may be a signal indicating that no further trim value adjustment is required, but the present disclosure is not limited thereto.

In one embodiment, the signal correction system 100 further includes a current detector 150, and the current detector 150 is configured to output the first detection signal SVI according to a charging signal SVBUS.

For example, the charging signal SVBUS may be a charging voltage or charging current from a power source. The first detection signal SVI may be configured to detect the ground line-related signal (such as the ground line signal SR2 of the current detector 150A), but the present disclosure is not limited thereto.

In some embodiments, the digital signal processor 130 may be a baseboard management controller (BMC) detector and bit recovery block, but the present disclosure is not limited thereto.

In some embodiments, the trim value adjuster 110 may simultaneously or sequentially output the first trim signals SLT, SMT, and SHT. The comparator group 120 may simultaneously or sequentially output the first slice signals SDLT, SDMT, and SDHT. The digital signal processor 130 may simultaneously receive and compare the voltage levels of the first slice signals SDLT, SDMT, and SDHT to output the power delivery (PD) packet content.

For example, the power delivery (PD) packet content may include, or correspond to, the permitted packet feedback message (GoodCRC_PASS), the error packet feedback message (GoodCRC_Error), the packet start signal SPS, and the packet end signal SPE, but the present disclosure is not limited thereto.

In some embodiments, since the PD packet transmission specification defines that the receiving end of a correctly received packet must return a GoodCRC packet, the digital signal processing block (such as Packet Decoder or the digital signal processor 130) will process and output four signals: the permitted packet feedback message (GoodCRC_PASS), the error packet feedback message (GoodCRC_Error), the packet start signal SPS, and the packet end signal SPE. This allows the artificial intelligence/machine learning module (AI ML block, corresponding to the processor 140) to, upon detecting the occurrence of an error packet feedback message (GoodCRC_Error) flag, enable the signal correction system 100 to immediately determine the current system load condition (or the amount of current being drawn) and the resulting ground voltage drop (GND IR drop), and then adjust the trim values of the trim signals SLT, SMT, and SHT as well as the slice signals SDLT, SDMT, and SDHT, but the present disclosure is not limited thereto.

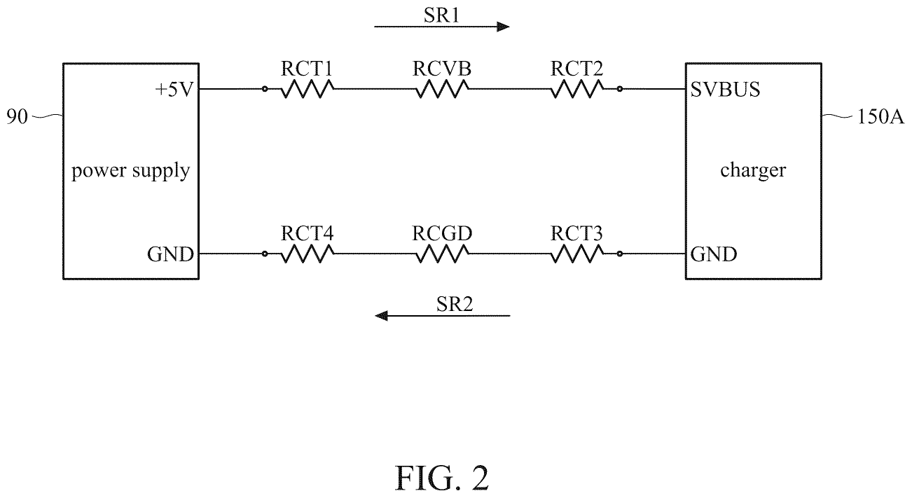

FIG. 2 is a block diagram of a charger of a signal correction system according to one embodiment of the present disclosure. As shown in FIG. 2, in one embodiment, FIG. 2 has a power supply 90, a charger 150A, a first resistor RCT1, a second resistor RCT2, a third resistor RCT3, a fourth resistor RCT4, a fifth resistor RCVB, and a sixth resistor RCGD. The power supply 90 has an output terminal +5V and a ground terminal GND. The charger 150A has a ground terminal GND and may output a charging signal SVBUS.

In some embodiments, the first resistor RCT1, the second resistor RCT2, and the fifth resistor RCVB may be connected in series between the power supply 90 and the charger 150A, and the first resistor RCT1, the second resistor RCT2, and the fifth resistor RCVB may transmit a signal SR1.

For example, the signal SR1 may be related to the first resistor RCT1, the second resistor RCT2, and the fifth resistor RCVB, but the present disclosure is not limited thereto. In some embodiments, the signal SR1 may be related to Ohm's law, but the present disclosure is not limited thereto. In some embodiments, the signal SR1 may be related to an output voltage value (such as 5 volt (V)) of the output terminal +5V and the charging signal SVBUS, but the present disclosure is not limited thereto.

In some embodiments, the third resistor RCT3, the fourth resistor RCT4, and the sixth resistor RCGD may be connected in series between the power supply 90 and the charger 150A, and the third resistor RCT3, the fourth resistor RCT4, and the sixth resistor RCGD may transmit the ground line signal SR2.

For example, the ground line signal SR2 may be related to the third resistor RCT3, the fourth resistor RCT4, and the sixth resistor RCGD, but the present disclosure is not limited thereto. Further, the ground line signal SR2 may be related to Ohm's law. In some embodiments, the ground line signal SR2 may be related to a voltage drop (or also referred to as the IR drop) between the ground terminal GND of the power supply 90 and the ground terminal GND of the charger 150A, but the present disclosure is not limited thereto.

In some embodiments, the ground line signal SR2 shown in FIG. 2 may correspond to the first impedance data SR shown in FIG. 1, but the present disclosure is not limited thereto.

In some embodiments, charger 150A shown in FIG. 2 may correspond to the current detector 150 shown in FIG. 1, but the present disclosure is not limited thereto.

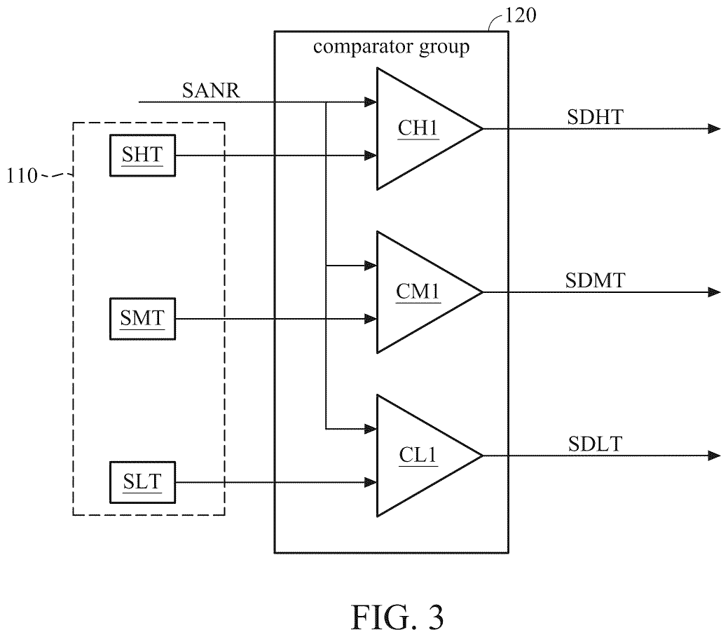

FIG. 3 is a block diagram of a comparator group of a signal correction system according to one embodiment of the present disclosure. As shown in FIG. 3, in one embodiment, the trim value adjuster 110 and the comparator group 120 shown in FIG. 3 may correspond to the trim value adjuster 110 and the comparator group 120 shown in FIG. 1, and the comparator group 120 includes a plurality of comparators CL1, CM1, and CH1.

In this embodiment, the trim value adjuster 110 may simultaneously or sequentially output the trim signals SLT, SMT, and SHT to the plurality of comparators CL1, CM1, and CH1. The trim value adjuster 110 may receive the signal SANR. The comparator CL1 may output the slice signal SDLT according to the signal SANR and the trim signal SLT. The comparator CM1 may output the slice signal SDMT according to the signal SANR and the trim signal SMT. The comparator CH1 may output the slice signal SDHT according to the signal SANR and the trim signal SHT.

For example, the signal SANR may correspond to the reference signal SCC of FIG. 1. The signal SANR may also be a data packet signal from the CC pin, but the present disclosure is not limited thereto.

Please refer to FIG. 1 to FIG. 3, in one embodiment, the trim value adjuster 110 may output the second trim signal (such as a different level signal of the first trim signal SLT) according to the second result signal SLR12. In this embodiment, the comparator group 120 may output the second slice signal (such as a different level signal of the first slice signal SDLT) to the digital signal processor 130 according to the first reference signal SCC and the second trim signal. The voltage level of the second slice signal is greater than or equal to the voltage level of the first slice signal SDLT.

For example, the second trim signal may be a lower-level signal of the first trim signal SLT, and the second slice signal may be a lower-level signal of the first slice signal SDLT. The digital signal processor 130 may output a permitted packet feedback message (GoodCRC_PASS) to the processor 140 according to the second slice signal, but the present disclosure is not limited thereto.

Furthermore, the signal correction system 100 may, by using the second trim signal and the second slice signal, further increase the allowable ground (GND) voltage.

In some embodiments, the relationship between the first slice signal SDLT and the second slice signal may be as shown in Table 1.

TABLE 1

| slice | | slice | | slice | |
|---|---|---|---|---|---|
| signal | voltage | signal | voltage | signal | voltage |
| (slice_1 | level | (slice_m | level | (slice_h | level |
| [1:0]) | (V) | [2:0]) | (V) | [1:0]) | (V) |
| 0 | 0.18 | 0 | 0.44 | 0 | 0.84 |
| 1 | 0.2 | 1 | 0.46 | 1 | 0.86 |
| 2 | 0.22 | 2 | 0.48 | 2 | 0.88 |
| 3 | 0.24 | 3 | 0.5 | 3 | 0.9 |
| 4 | 0.26 | 4 | 0.52 | | |
| 5 | 0.28 | 5 | 0.54 | | |
| 6 | 0.3 | 6 | 0.56 | | |
| 7 | 0.32 | 7 | 0.58 | | |

For example, the first slice signal (slice_1[1:0]) may be 3, the first slice signal (slice_m[2:0]) may be 4, and the first slice signal (slice_h[1:0]) may be 0. In this case, the voltage corresponding to the first slice signal (slice_1[1:0]) may be 0.24 volts (V), the voltage corresponding to the first slice signal (slice_m[2:0]) may be 0.52 V, and the voltage corresponding to the first slice signal (slice_h[1:0]) may be 0.84 V, but the present disclosure is not limited thereto.

In some embodiments, if the initial default values are: the first slice signal (slice_1[1:0]) is 3, the first slice signal (slice_m[2:0]) is 4, and the first slice signal (slice_h[1:0]) is 0, under these conditions, the signal correction system 100 may allow a ground (GND) voltage rise of 250 mV to 300 mV. When the system reaches a ground (GND) voltage rise of 350 mV, the actually allowable voltage increases by 50 mV.

Further, the signal correction system 100 may adjust the slice[2:0], that is, slice_L/M/H, with relative trim value changes when the processor 140 detects the occurrence of the error packet feedback message (GoodCRC_Error) flag. This facilitates the signal correction system 100 to effectively detect packet bit content during retransmission and to output the permitted packet feedback message (GoodCRC_PASS).

Then, when the signal correction system 100 applies the relative trim value changes, the voltage corresponding to the second slice signal (slice_1[1:0]) may increase from 0.24 V to 0.3 V, the voltage corresponding to the second slice signal (slice_m[2:0]) may increase from 0.52 V to 0.56 V, and the voltage corresponding to the second slice signal (slice_h[1:0]) may increase from 0.84 V to 0.9 V. At this time, the second slice signal (slice_1[1:0]) may be 6, the second slice signal (slice_m[2:0]) may be 6, and the second slice signal (slice_h[1:0]) may be 3, but the present disclosure is not limited thereto.

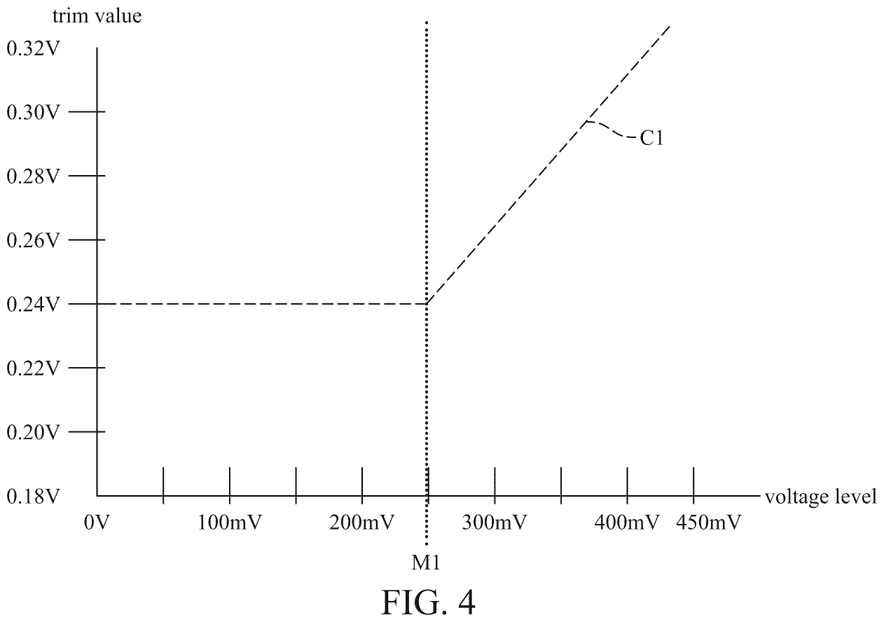

FIG. 4 is a diagram of a plurality of signal trends of a signal correction system according to one embodiment of the present disclosure. As shown in FIG. 4, in one embodiment, FIG. 4 includes a data trend line C1, and the data trend line C1 is related to the voltage level (i.e., the horizontal axis) of the ground line and a trim value (i.e., the vertical axis).

For example, the above-mentioned ground voltage level (such as DC offset level) may correspond to the first detection signal SVI of FIG. 1 or the ground line signal SR2 of FIG. 2. The above-mentioned trim value may correspond to, or be related to, the trim signals SLT, SMT, and/or SHT, but the present disclosure is not limited thereto.

In some embodiments, FIG. 4 may further include a threshold M1. When a portion of the data trend line C1 is located below the threshold M1, that portion of the data trend line C1 may exhibit a horizontal trend. When another portion of the data trend line C1 is located above the threshold M1, that portion of the data trend line C1 may exhibit a positive trend (also referred to as a positive slope trend)

For example, the threshold M1 may be 250 mV. When the ground voltage level is within a range of 0 to 250 mV, the trim value may correspond to 0.24 V. When the ground voltage level is greater than 250 mV, the trim value may correspond to a value greater than 0.24 V, but the present disclosure is not limited thereto.

Please refer to FIG. 1 and FIG. 4, in one embodiment, the processor 140 constructs a first data trend line C1 according to the (corresponding) detection signals and the (corresponding) slice signals. The processor 140 updates the learning algorithm according to the first data trend line C1. The plurality of detection signals include the first detection signal SCC, and the plurality of slice signals include the first slice signal SDLT, SDMT, and/or SDHT.

For example, the voltage level (i.e., the horizontal axis) of the ground line may correspond to a plurality of detection signals, and the trim value (i.e., the vertical axis) may correspond to a plurality of slice signals, but the present disclosure is not limited thereto.

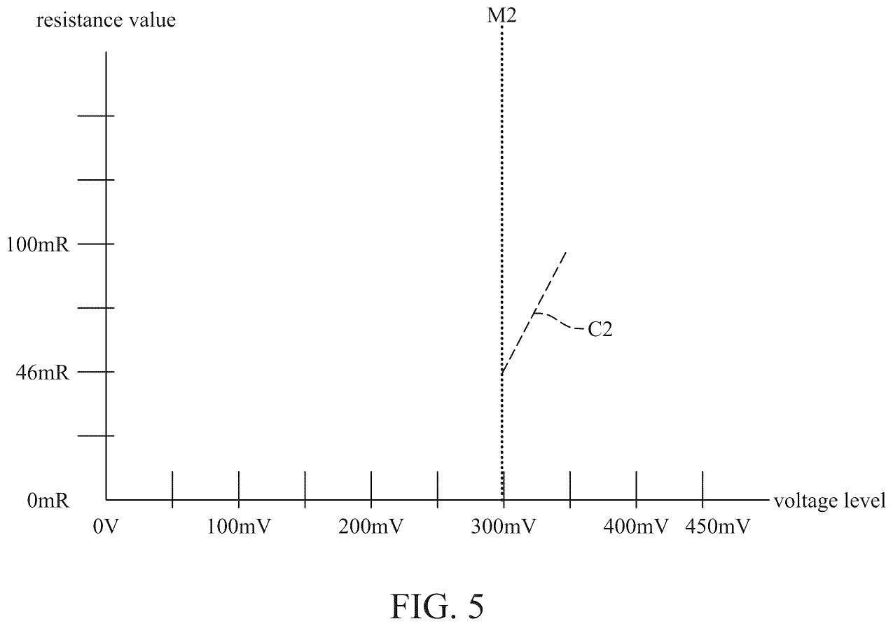

FIG. 5 is a diagram of a plurality of signal trends of a signal correction system according to one embodiment of the present disclosure. As shown in FIG. 5, in one embodiment, FIG. 5 includes a data trend line C2, and the data trend line C2 is related to the voltage level (i.e., the horizontal axis) of the ground line and a resistance value (i.e., the vertical axis).

For example, the above-mentioned voltage level (such as the DC offset level) of ground line may correspond to the first detection signal SVI in FIG. 1 or the ground line signal SR2 in FIG. 2, and the above-mentioned resistance value may correspond to (or be related to) the first impedance data SR in FIG. 1 or the resistances RCT3, RCT4, and/or RCGD in FIG. 2, but the present disclosure is not limited thereto.

In some embodiments, FIG. 5 may further include a threshold M2. When a portion of the data trend line C2 is located below the threshold M2, that portion of the data trend line C2 may have no valid value. When another portion of the data trend line C2 is located above the threshold M2, that portion of the data trend line C2 may exhibit a positive trend (also referred to as a positive slope trend).

For example, the threshold M2 may be 300 mV. When the voltage level of the ground line is 300 mV, the resistance value may correspond to 46 milliohms (m (2). When the voltage level of the ground line is greater than 300 mV, the resistance value may be greater than 46 milliohms, but the present disclosure is not limited thereto.

In some embodiments, when the voltage level of the ground line is 350 mV, the resistance value may be 100 milliohms, but the present disclosure is not limited thereto. In some embodiments, the resistance value may be a measured value obtained when a current of the ground line signal SR2 in FIG. 2 is 3.5 amperes (A), but the present disclosure is not limited thereto.

Please refer to FIG. 1 and FIG. 5, in one embodiment, the processor 140 constructs a second data trend line C2 according to the (corresponding) detection signals and the (corresponding) impedance data. The processor 140 updates the learning algorithm according to the second data trend line C2. The plurality of impedance data includes the first impedance data SR.

For example, the voltage level (i.e., the horizontal axis) of the ground line may correspond to a plurality of detection signals, and the resistance value (i.e., the vertical axis) may correspond to a plurality of impedance data, but the present disclosure is not limited thereto.

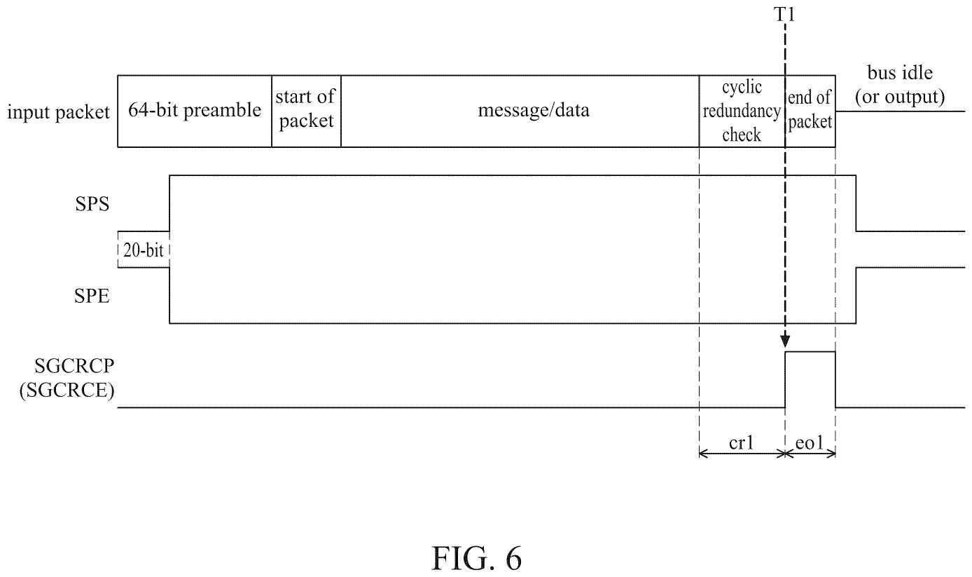

FIG. 6 is a diagram of a plurality of signal levels of a signal correction system according to one embodiment of the present disclosure. As shown in FIG. 6, in one embodiment, FIG. 6 includes input packet data, packet start signal SPS, the packet end signal SPE, first packet feedback data SGCRC [symbol] second packet feedback data SGCRCE.

For example, the start signal SPS, the packet end signal SPE, the first packet feedback data SGCRC, and the second packet feedback data SGCRCE in FIG. 6 may respectively correspond to the start signal SPS, the packet end signal SPE, the first packet feedback data SGCRC, and the second packet feedback data SGCRCE in FIG. 1, but the present disclosure is not limited thereto.

At this time, the first packet feedback data SGCRC may be the permitted packet feedback message (GoodCRC_PASS), and the second packet feedback data SGCRCE may be the error packet feedback message (GoodCRC_Error), but the present disclosure is not limited thereto.

In some embodiments, the input packet data in FIG. 6 includes a 64-bit preamble interval, a start-of-packet (SOP) interval, a message and data interval, a check interval cr1 (such as a cyclic redundancy check (CRC) interval), an end-of-packet (EOP) interval eo1, and an output interval.

For example, the last several intervals of the input packet data may output the first packet feedback data SGCRC or the second packet feedback data SGCRCE to the processor 140, but the present disclosure is not limited thereto.

In some embodiments, the input packet data may correspond to a power delivery (PD) packet format or a CC-to-digital converted signal (such as CC convert to digital signal), but the present disclosure is not limited thereto.

Please refer to FIG. 1 and FIG. 6, in one embodiment, the digital signal processor 130 outputs packet data, and the packet data includes a check interval cr1, a packet end interval eo1, and a trigger time point T1. At the trigger time point T1, the digital signal processor 130 outputs first packet feedback data SGCRC to the processor 140. The trigger time point T1 is (located) after the check interval cr1, and the packet end interval eo1 is (located) after the trigger time point T1.

For example, at the trigger time point T1, the digital signal processor 130 may output the first packet feedback data SGCRC or the second packet feedback data SGCRCE to the processor 140, and the trigger time point T1 may be located between the check interval cr1 and the packet end interval eo1, but the present disclosure is not limited thereto.

In some embodiments, the trigger time point T1 may be adjusted to any interval or time point in the packet data according to usage requirements, but the present disclosure is not limited thereto.

FIG. 7 is a block diagram of a signal correction system according to one embodiment of the present disclosure. As shown in FIG. 7, in one embodiment, the signal correction system 100A of FIG. 7 includes a trim value adjuster 110A, a comparator group 120A, a digital signal processor 130A, and a processor 140A.

For example, the signal correction system 100A, the trim value adjuster 110A, the comparator group 120A, the digital signal processor 130A, and the processor 140A shown in FIG. 7 may respectively correspond to the signal correction system 100, the trim value adjuster 110, the comparator group 120, the digital signal processor 130, and the processor 140 shown in FIG. 1, but the present disclosure is not limited thereto.

Furthermore, some operations of FIG. 7 may correspond to some operations of FIG. 1. For the sake of brevity in the specification, detailed descriptions thereof are omitted herein.

It is worth noting that, in one embodiment, the signal correction system 100A further includes a filter 160A. The filter 160A is coupled to the comparator group 120A. The filter 160A filters the first reference signal SCC and outputs a waveform signal SAR to the comparator group 120A.

In one embodiment, the signal correction system 100A may include step S10. In the step S10, waveform widths and/or corresponding slopes are obtained.

For example, the processor 140A may respectively obtain waveform widths or slopes among a plurality of waveforms based on the slice signals SDLT, SDMT, and SDHT output from the comparator group 120A. At this time, the slice signals SDLT, SDMT, and SDHT may respectively correspond to the waveform signal SAR, but the present disclosure is not limited thereto. In addition, waveform characteristics of the slice signals SDLT, SDMT, and SDHT may be similar to waveform characteristics among a plurality of waveform signals SAR, but the present disclosure is not limited thereto.

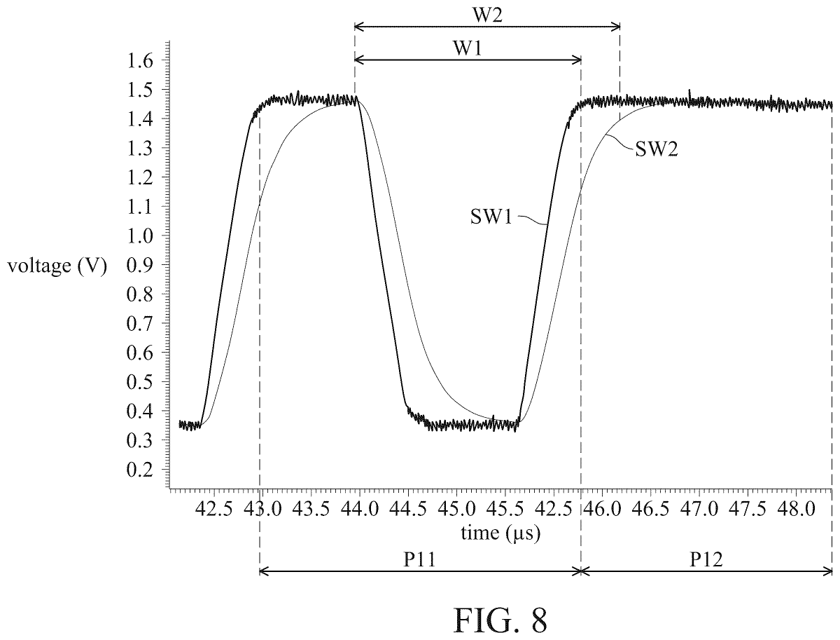

FIG. 8 is a waveform diagram of a waveform signal of a signal correction system according to one embodiment of the present disclosure. As shown in FIG. 8, in one embodiment, FIG. 8 includes a first waveform signal SW1, a second waveform signal SW2, a first interval P11, and a second interval P12. The first waveform signal SW1 has a first wavelength width W1. The second waveform signal SW2 has a second wavelength width W2.

For example, in the first interval P11, the first waveform signal SW1 may correspond to data “1” of a BMC signal (which may correspond to a low level), and in the second interval P12, the first waveform signal SW1 may correspond to data “0” of the BMC signal (which may correspond to a high level), but the present disclosure is not limited thereto.

In addition, at different timings, the waveform of the first waveform signal SW1 may be inverted. For example, in a third interval, the first waveform signal SW1 may correspond to data “0” of the BMC signal (which may correspond to a low level), and in a fourth interval, the first waveform signal SW1 may correspond to data “1” of the BMC signal (which may correspond to a high level). The third interval is (located) after the second interval P12, and the fourth interval is (located) after the third interval, but the present disclosure is not limited thereto.

In some embodiments, the duration of the second interval P12 may be approximately equal to the duration of the first interval P11, but the present disclosure is not limited thereto. In some embodiments, the duration of the second interval P12 may be approximately twice the duration of the first interval P11, but the present disclosure is not limited thereto. In some embodiments, the duration of the second interval P12 may be greater than the duration of the first interval P11, but the present disclosure is not limited thereto.

Please refer to FIG. 7 and FIG. 8, in some embodiments, during the PD charging process (of the signal correction system 100A), the CC signals under different load currents (such as the detection signal SCC) may exhibit different waveform outputs after passing through the filter 160A due to different voltage rise effects (such as the first waveform signal SW1 and the second waveform signal SW2 in FIG. 8).

Furthermore, at a voltage rise of 470 mV, the waveform at the CC pin (such as the first waveform signal SW1) and the waveform after being analog-RC filtered (such as the second waveform signal SW2) show that as the PD charging load current increases, the low-level (or LOW level) distortion of the second waveform signal SW2 becomes more pronounced (i.e., the waveform width becomes narrower).

Therefore, the present disclosure may utilize the existing circuit (corresponding to the signal SANR circuit in FIG. 3) under no-load-current conditions to address techniques and methods for improving packet detection and correct transmission response under different load conditions.

In one embodiment, the filter 160A outputs the waveform signal SAR according to the first reference signal SCC, and the waveform signal SAR may correspond to the first waveform signal SW1 and the second waveform signal SW2.

For example, the second waveform signal SW2 may have a hierarchical relationship with the first waveform signal SW1, but the present disclosure is not limited thereto.

In one embodiment, the first wavelength width W1 of the first waveform signal SW1 along the first axial direction is smaller than the second wavelength width W2 of the second waveform signal SW2 along the first axial direction.

For example, the first axial direction may be the horizontal axis (or time axis). The first wavelength width W1 may be the width between waveform turning points of the first waveform signal SW1, and the second wavelength width W2 may be the width between waveform turning points of the second waveform signal SW2, but the present disclosure is not limited thereto.

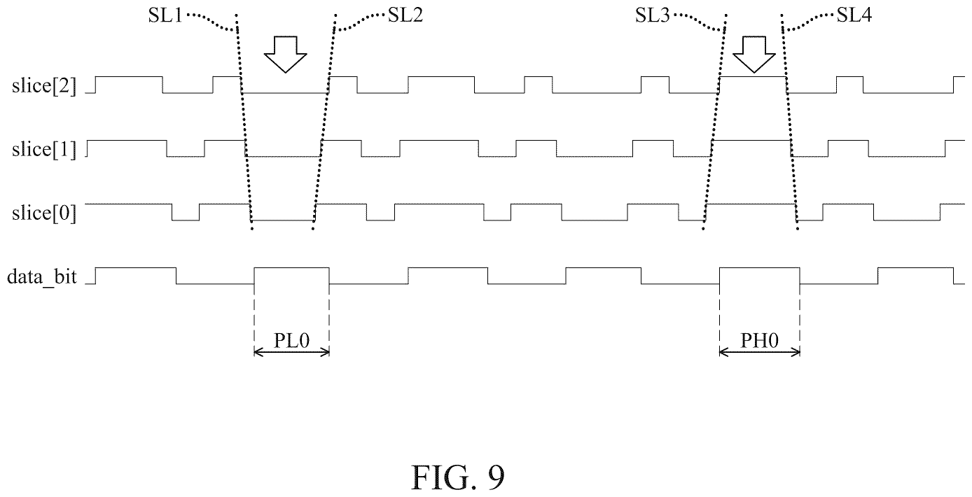

FIG. 9 is a waveform diagram of a plurality of signals of a signal correction system according to one embodiment of the present disclosure. As shown in FIG. 9, in one embodiment, FIG. 9 includes bit data data_bit and a plurality of slice waveform signals slice[0], slice[1], and slice[2]. The bit data data_bit includes a first interval PLO and a second interval PHO.

For example, in the first interval PLO, the plurality of slice waveform signals slice[0], slice[1], and slice[2] may correspond to the data “0” of the low-level, and in the second interval PHO, the plurality of slice waveform signals slice[0], slice[1], and slice[2] may correspond to the data “0” of the high-level, but the present disclosure is not limited thereto.

In some embodiments, the plurality of slice waveform signals slice[0], slice[1], and slice[2] may correspond to the slice signal SDLT of FIG. 1 or FIG. 7, but the present disclosure is not limited thereto. In some embodiments, the plurality of slice waveform signals slice[0], slice[1], and slice[2] may correspond to the slice signal SDMT of FIG. 1 or FIG. 7, but the present disclosure is not limited thereto. In some embodiments, the plurality of slice waveform signals slice[0], slice[1], and slice[2] may correspond to the slice signal SDHT of FIG. 1 or FIG. 7, but the present disclosure is not limited thereto.

In some embodiments, between the plurality of slice waveform signals slice[0], slice[1], and slice[2], there may be first slope data SL1, second slope data SL2, third slope data SL3, and/or fourth slope data SL4.

For example, the first slope data SL1 may be a negative slope, the second slope data SL2 may be a positive slope, the third slope data SL3 may be a positive slope, and the fourth slope data SL4 may be a negative slope, but the present disclosure is not limited thereto.

In some embodiments, the first slope data SL1, second slope data SL2, third slope data SL3, and/or fourth slope data SL4 of FIG. 9 may be related to the first wavelength width W1 and the second wavelength width W2 of FIG. 8.

For example, since the length of the second wavelength width W2 is greater than that of the first wavelength width W1, a plurality of slopes may occur between the opening differences (or width differences) caused by the second wavelength width W2 and the first wavelength width W1, but the present disclosure is not limited thereto.

In some embodiments, FIG. 9 may be the digitalized result of FIG. 8, but the present disclosure is not limited thereto. In some embodiments, the plurality of slice waveform signals slice[0] and slice[1] of FIG. 9 may respectively correspond to the first waveform signal SW1 and the second waveform signal SW2 of FIG. 8, but the present disclosure is not limited thereto.

Please refer to FIG. 7 to FIG. 9, in one embodiment, the comparator group 120A outputs the slice signal SDLT (such as the first slice waveform signal slice[0] and the second slice waveform signal slice[1] shown in FIG. 9) according to the waveform signal SAR (i.e., first waveform signal SW1, second waveform signal SW2) and the first trim signal SLT.

In this embodiment, the digital signal processor 130A outputs third packet feedback data according to the first slice waveform signal slice[0] and/or the second slice waveform signal slice[1]. The processor 140A outputs a third result signal to trim value adjuster 110A according to the third packet feedback data using the learning algorithm.

For example, the third packet feedback data may be the permitted packet feedback message (GoodCRC_PASS) or the error packet feedback message (GoodCRC_Error), but the present disclosure is not limited thereto.

In one embodiment, the processor 140A obtains the first slope data SL1 according to the first slice waveform signal slice[0] and the second slice waveform signal slice[1]. The processor 140A updates the learning algorithm according to the first slope data SL1.

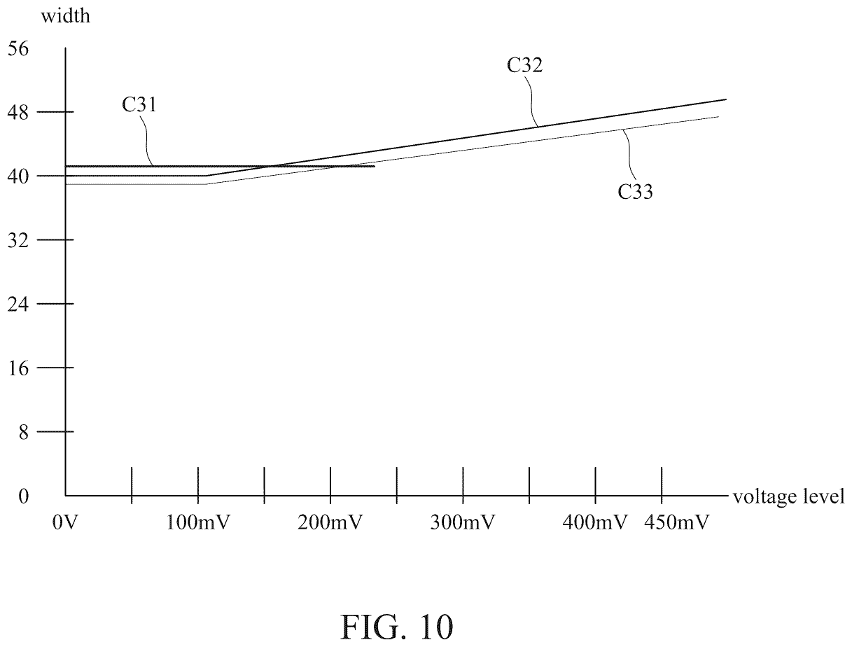

FIG. 10 is a diagram of a plurality of signal trends of a signal correction system according to one embodiment of the present disclosure. As shown in FIG. 10, in one embodiment, FIG. 10 includes a plurality of data trend lines C31, C32, and C33, and the plurality of data trend lines C31, C32, and C33 are related to the voltage level (i.e., horizontal axis) and the wavelength width (i.e., vertical axis) of the ground line.

For example, the plurality of data trend lines C31, C32, and C33 may be related to the first slope data SL1, second slope data SL2, third slope data SL3, or fourth slope data SL4 of FIG. 9, but the present disclosure is not limited thereto.

In some embodiments, the data trend line C31 may be obtained from the slice waveform signals slice[0], slice[1], and/or slice[2] of FIG. 9, but the present disclosure is not limited thereto. In some embodiments, the data trend line C32 may be obtained from the slice waveform signals slice[0], slice[1], and/or slice[2] of FIG. 9, but the present disclosure is not limited thereto. In some embodiments, the data trend line C33 may be obtained from the slice waveform signals slice[0], slice[1], and/or slice[2] of FIG. 9, but the present disclosure is not limited thereto.

In some embodiments, when the slice waveform signals slice[0], slice[1], and/or slice[2] of FIG. 9 correspond to high-level data “0”, the plurality of data trend lines C31, C32, and C33 may be obtained, but the present disclosure is not limited thereto.

In some embodiments, the wavelength width (i.e., vertical axis) may be a slice counter, but the present disclosure is not limited thereto.

In some embodiments, the data trend line C31 may be related to the slice signal SDLT of FIG. 7, the data trend line C32 may be related to the slice signal SDMT of FIG. 7, and the data trend line C33 may be related to the slice signal SDHT of FIG. 7, but the present disclosure is not limited thereto.

In some embodiments, the trend of data trend line C31 may remain horizontal with respect to the voltage level of the ground line, but the present disclosure is not limited thereto.

In some embodiments, when a portion of data trend line C32 is below a threshold, that portion may exhibit a horizontal trend. When another portion of data trend line C32 is above the threshold, that portion may exhibit a positive trend (also referred to as a positive slope trend).

In some embodiments, when a portion of data trend line C33 is below a threshold, that portion may exhibit a horizontal trend. When another portion of data trend line C33 is above the threshold, that portion may exhibit a positive trend (also referred to as a positive slope trend).

Please refer to FIG. 7 to FIG. 10, in some embodiments, the processor 140A obtains first slice count data and second slice count data according to the first slice waveform signal slice[0] and the second slice waveform signal slice[1], respectively. The processor 140A constructs the third data trend line C31 according to the (corresponding) ground signals and the (corresponding) slice count data. The processor 140A updates the learning algorithm according to the third data trend line C31. The plurality of slice count data includes the first slice waveform signal slice[0] and the second slice waveform signal slice[1].

For example, the plurality of slice count data may relate to the wavelength width (i.e., vertical axis) of FIG. 10, and the plurality of ground signals may relate to the voltage level (i.e., horizontal axis) of the ground line of FIG. 10, but the present disclosure is not limited thereto. In addition, data trend lines C32 and C33 may perform the same operations as described above. For brevity of the specification, further description is omitted herein.

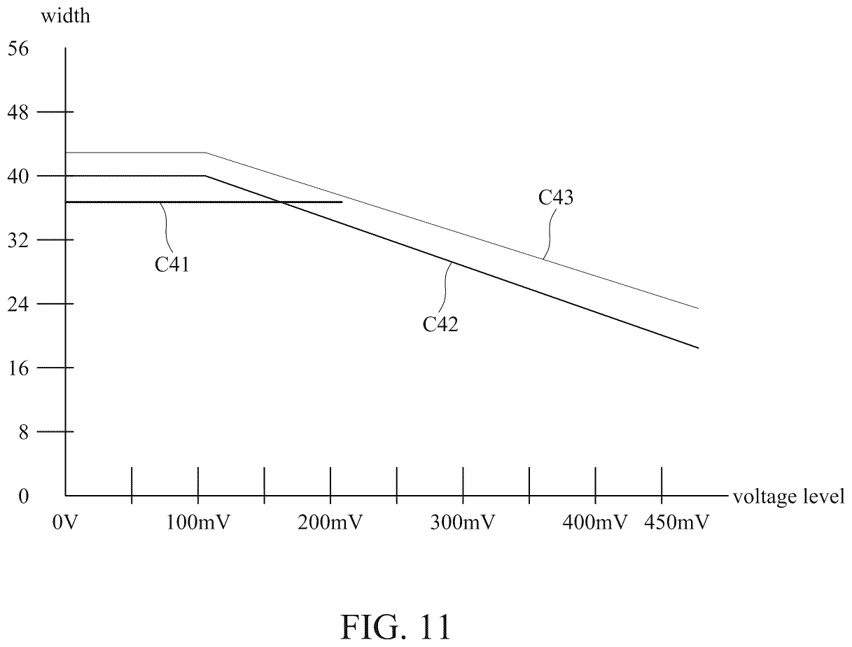

FIG. 11 is a diagram of a plurality of signal trends of a signal correction system according to one embodiment of the present disclosure. As shown in FIG. 11, in one embodiment, FIG. 11 includes a plurality of data trend lines C41, C42, and C43, and the plurality of data trend lines C41, C42, and C43 are related to the voltage level (i.e., horizontal axis) of the ground line and the wavelength width (i.e., vertical axis).

For example, the plurality of data trend lines C41, C42, and C43 may be related to the first slope data SL1, second slope data SL2, third slope data SL3, or fourth slope data SL4 of FIG. 9, but the present disclosure is not limited thereto.

In some embodiments, the data trend line C41 may be obtained from the slice waveform signals slice[0], slice[1], and/or slice[2] of FIG. 9, but the present disclosure is not limited thereto. In some embodiments, the data trend line C42 may be obtained from the slice waveform signals slice[0], slice[1], and/or slice[2] of FIG. 9, but the present disclosure is not limited thereto. In some embodiments, the data trend line C43 may be obtained from the slice waveform signals slice[0], slice[1], and/or slice[2] of FIG. 9, but the present disclosure is not limited thereto.

In some embodiments, when the slice waveform signals slice[0], slice[1], and/or slice[2] of FIG. 9 correspond to the data “0” of the low-level, a plurality of data trend lines C41, C42, and C43 may be obtained, but the present disclosure is not limited thereto.

In some embodiments, the data trend line C41 may be related to the slice signal SDLT of FIG. 7, the data trend line C42 may be related to the slice signal SDMT of FIG. 7, and the data trend line C43 may be related to the slice signal SDHT of FIG. 7, but the present disclosure is not limited thereto.

In some embodiments, the trend of data trend line C41 may remain horizontal with respect to the voltage level of the ground line, but the present disclosure is not limited thereto.

In some embodiments, when a portion of data trend line C42 is below a threshold, that portion may exhibit a horizontal trend. When another portion of data trend line C42 is above the threshold, that portion may exhibit a negative trend (also referred to as a negative slope trend).

In some embodiments, when a portion of data trend line C43 is below a threshold, that portion may exhibit a horizontal trend. When another portion of data trend line C43 is above the threshold, that portion may exhibit a negative trend (also referred to as a negative slope trend).

FIG. 12A is a flowchart of a signal correction method according to one embodiment of the present disclosure. FIG. 12B is a flowchart of a signal correction method according to one embodiment of the present disclosure. As shown in FIG. 12A and FIG. 12B, in one embodiment, the signal correction method 1200 includes a plurality of steps 1210 to1270, and the following content will further describe a plurality of steps 1210 to 1270.

In the step 1210, outputting a first result signal by a learning algorithm according to a first detection signal, first impedance data, and first packet feedback data.

In the step 1220, outputting a first trim signal according to the first result signal.

In one embodiment, the processor 140 shown in FIG. 1 may output the first result signal SLR1 by the learning algorithm according to first detection signal SVI, first impedance data SR [symbol] first packet feedback data SGCRCP

In the step 1230, outputting a first slice signal according to a first reference signal and the first trim signal.

In one embodiment, the comparator group 120 shown in FIG. 1 may output the first slice signal SDLT according to the first reference signal SCC and the first trim signal SLT

In the step 1240, outputting second packet feedback data according to the first slice signal.

In one embodiment, the digital signal processor 130 shown in FIG. 1 may output the second packet feedback data SGCRCE according to first slice signal SLT.

In the step 1250, outputting a second result signal by using the learning algorithm according to the second packet feedback data.

In one embodiment, the processor 140 shown in FIG. 1 may output the second result signal SLR12 to the trim value adjuster 110 by the learning algorithm according to the second packet feedback data SGCRCE.

In the step 1260, outputting packet data according to the second result signal. In addition, the packet data includes the check interval, the packet end interval, and the trigger time point.

In one embodiment, the digital signal processor 130 shown in FIG. 1 may output the packet data, and the packet data includes the check interval cr1, the packet end interval eo1, and the trigger time point T1.

In the step 1270, at the trigger time point, outputting the second packet feedback data to a processor.

In one embodiment, at the trigger time point T1, the digital signal processor 130 shown in FIG. 1 may output the second packet feedback data SGCRCE (or the first packet feedback data SGCRC) to the processor 140.

It should be understood that the above steps do not need to be executed sequentially, and each feature of the embodiments shown in FIG. 1 through FIG. 11 may be applied to the signal correction method of FIG. 12A and FIG. 12B.

Please refer to FIG. 1 to FIG. 12B, in one embodiment, the signal correction method 1200 further includes the following steps: outputting a first detection signal SVI according to the charging signal SVBUS; constructing a first data trend line C1 according to the (corresponding) detection signals and the (corresponding) slice signals; constructing a second data trend line C2 according to the (corresponding) detection signals and the (corresponding) impedance data, and updating the learning algorithm according to the first data trend line C1 and/or the second data trend line C2. Wherein the plurality of detection signals include the first detection signal SCC, the plurality of slice signals includes first slice signals SDLT, SDMT, and/or SDHT, and the plurality of impedance data includes first impedance data SR. The first data trend line C1 and the second data trend line C2 are each related to the voltage level of the ground line.

In one embodiment, the signal correction method 1200 further includes the following step: outputting a first waveform signal SW1 and a second waveform signal SW2 according to the first reference signal SCC. Wherein the first waveform signal SW1 has a first wavelength width W1 along the first axial direction (such as the time axis) that is smaller than the second wavelength width W2 of the second waveform signal along the first axial direction. The first waveform signal SW1 and the second waveform signal SW2 are each related to the baseboard management controller (BMC) signal.

In one embodiment, the signal correction method 1200 further includes the following steps: outputting a first slice waveform signal slice[0] and a second slice waveform signal slice[1] according to the first waveform signal SW1, the second waveform signal SW2, and the first trim signal SLT; outputting a third packet feedback data according to the first slice waveform signal slice[0] and/or the second slice waveform signal slice[1]; and outputting a third result signal to the trim value adjuster 110A via the learning algorithm according to the third packet feedback data. The third packet feedback data includes either the permitted packet feedback message or the error packet feedback message.

In one embodiment, the signal correction method 1200 further includes the following steps: obtaining first slope data SL1 according to the first slice waveform signal slice[0] and the second slice waveform signal slice[1]; and updating the learning algorithm according to the first slope data SL1. The first slope data is related to the first wavelength width W1 and the second wavelength width W2.

In one embodiment, the signal correction method 1200 further includes the following steps: individually obtaining first slice count data and second slice count data according to the first slice waveform signal slice[0] and the second slice waveform signal slice[1]; constructing a third data trend line C31 according to corresponding ground signals and corresponding slice count data; and updating the learning algorithm according to the third data trend line C31. Wherein the plurality of slice count data includes the first slice waveform signal slice[0] and the second slice waveform signal slice[1], and the plurality of ground signals are related to the voltage level of the ground line.

In some embodiments, the signal correction system 100 may further include a memory, and the signal correction method 1200 can be stored in the memory. The memory may include random-access memory (RAM), read-only memory (ROM), cache, flash memory, memory cards, hard drives (such as cloud/network/external hard drives), optical discs, USB drives, or databases, but the present disclosure is not limited thereto.

In some embodiments, the signal correction method 1200 may be implemented as any type of programming code, algorithm, software, or firmware, but the present disclosure is not limited thereto.

In some embodiments, the signal correction method 1200 may be implemented by the signal correction system 100, but the present disclosure is not limited thereto. In some embodiments, the signal correction method 1200 may be implemented via a non-transitory computer-readable storage medium, but the present disclosure is not limited thereto. In some embodiments, the signal correction method 1200 may be implemented by other systems or servers, but the present disclosure is not limited thereto.

Therefore, according to the technical content of the present disclosure, the signal correction system and signal correction method shown in the embodiment of the present disclosure can achieve the effect of stably receiving correct packet data by continuously and dynamically adjusting trim values.

In addition, it should be understood that the ordinal terms such as “first” “second” and the like used in the specification and the claims are employed to modify elements and are not intended to indicate any temporal order of the element(s), nor do they imply any sequence between elements or any sequence in a manufacturing process. The sole purpose of these ordinals is to clearly distinguish elements having similar names from one another. The same terms used in the specification and in the claims need not correspond; for example, an element referred to as a first element in the specification may be referred to as a second element in the claims.

The scope of protection of the present disclosure is not limited to the processes, machines, manufactures, compositions of matter, devices, methods, and steps described in the specific embodiments of the specification. Any person of ordinary skill in the art will understand from the teachings of the present disclosure that existing or future-developed processes, machines, manufactures, compositions of matter, devices, methods, and steps may be used, so long as they can perform substantially the same function or achieve substantially the same result as those in the embodiments described herein. Accordingly, the scope of the present disclosure encompasses such processes, machines, manufactures, compositions of matter, devices, methods, and steps. Any embodiment or claim of the present disclosure does not need to achieve all of the objectives, advantages, and/or features disclosed herein.

The foregoing has outlined several embodiments to assist those of ordinary skill in the art in better understanding the concepts of the embodiments of the present disclosure. It should be understood by those of ordinary skill in the art that, based on the embodiments of the present disclosure, they may design or modify other processes and structures to achieve the same objectives and/or advantages as the embodiments described herein. It should also be understood that such equivalent processes and structures do not depart from the spirit and scope of the present disclosure, and that various changes, substitutions, and alterations can be made without departing from the spirit and scope of the present disclosure.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A signal correction system, comprising:
a trim value adjuster;
a comparator group, coupled to the trim value adjuster;
a digital signal processor, coupled to the comparator group; and
a processor, coupled to the trim value adjuster;
wherein the processor is configured to output a first result signal by a learning algorithm according to a first detection signal, first impedance data, and first packet feedback data;
wherein the trim value adjuster outputs a first trim signal according to the first result signal;
wherein the comparator group outputs a first slice signal according to a first reference signal and the first trim signal;
wherein the digital signal processor outputs second packet feedback data according to the first slice signal;
wherein the processor outputs a second result signal to the trim value adjuster by the learning algorithm according to the second packet feedback data.

2. The signal correction system as claimed in claim 1, wherein the trim value adjuster outputs a second trim signal according to the second result signal;
wherein the comparator group outputs a second slice signal to the digital signal processor according to a first reference signal and the second trim signal;
wherein a voltage level of the first slice signal is greater than or equal to a voltage level of the second slice signal.

3. The signal correction system as claimed in claim 1, further comprising:
a current detector, configured to output the first detection signal according to a charging signal;
wherein the processor constructs a first data trend line according to a plurality of detection signals and a plurality of slice signals;
wherein the processor updates the learning algorithm according to the first data trend line;
wherein the plurality of detection signals comprise the first detection signal;
wherein the plurality of slice signals comprise the first slice signal.

4. The signal correction system as claimed in claim 3, wherein
the processor constructs a second data trend line according to a plurality of detection signals and a plurality of impedance data;
wherein the processor updates the learning algorithm according to the second data trend line;
wherein the plurality of impedance data comprise the first impedance data.

5. The signal correction system as claimed in claim 1, wherein
the digital signal processor outputs packet data, and the packet data comprises a check interval, a packet end interval, and a trigger time point;
wherein, at the trigger time point, the digital signal processor outputs the first packet feedback data to the processor;
wherein the trigger time point is located after the check interval, and the packet end interval is located after the trigger time point.

6. The signal correction system as claimed in claim 1, further comprising:
a filter, configured to output a first waveform signal and a second waveform signal according to the first reference signal;
wherein a first wavelength width of the first waveform signal along a first axial direction is smaller than a second wavelength width of the second waveform signal along the first axial direction.

7. The signal correction system as claimed in claim 6, wherein
the comparator group outputs a first slice waveform signal and a second slice waveform signal according to the first waveform signal, the second waveform signal, and the first trim signal;
wherein the digital signal processor outputs third packet feedback data according to the first slice waveform signal and/or the second slice waveform signal;
wherein the processor outputs a third result signal to a trim value adjuster by the learning algorithm according to the third packet feedback data.

8. The signal correction system as claimed in claim 7, wherein
the processor obtains first slope data according to the first slice waveform signal and the second slice waveform signal;
wherein the processor updates the learning algorithm according to the first slope data.

9. The signal correction system as claimed in claim 7, wherein
the processor obtains first slice count data and second slice count data respectively according to the first slice waveform signal and the second slice waveform signal;
wherein the processor constructs a third data trend line according to a plurality of ground signals and a plurality of slice count data;
wherein the processor updates the learning algorithm according to the third data trend line;
wherein the plurality of slice count data comprises the first slice waveform signal and the second slice waveform signal.

10. A signal correction method, comprising:
outputting a first result signal by a learning algorithm according to a first detection signal, first impedance data, and first packet feedback data;
outputting a first trim signal according to the first result signal;
outputting a first slice signal according to a first reference signal and the first trim signal;
outputting second packet feedback data according to the first slice signal;
outputting a second result signal by the learning algorithm according to the second packet feedback data;
outputting packet data according to the second result signal, wherein the packet data comprises a check interval, a packet end interval and a trigger time point; and
during the trigger time point, outputting second packet feedback data to a processor.

11. The signal correction method as claimed in claim 10, further comprising:
outputting the first detection signal according to a charging signal;
constructing a first data trend line according to a plurality of detection signals and a plurality of slice signals;
constructing a second data trend line according to a plurality of detection signals and a plurality of impedance data; and
updating the learning algorithm according to the first data trend line and/or the second data trend line;
wherein the plurality of detection signals comprises the first detection signal, the plurality of slice signals comprises the first slice signal, and the plurality of impedance data comprises the first impedance data;
wherein the first data trend line and the second data trend line are respectively associated with a voltage level of a ground line.

12. The signal correction method as claimed in claim 10, further comprising:
outputting a first waveform signal and a second waveform signal according to the first reference signal;
wherein a first wavelength width of the first waveform signal along a first axial direction is smaller than a second wavelength width of the second waveform signal along the first axial direction;
wherein the first waveform signal and the second waveform signal are respectively associated with a baseboard management controller (BMC) signal.

13. The signal correction method as claimed in claim 12, further comprising:
outputting a first slice waveform signal and a second slice waveform signal according to the first waveform signal, the second waveform signal, and the first trim signal;
outputting third packet feedback data according to the first slice waveform signal and/or the second slice waveform signal; and
outputting a third result signal to a trim value adjuster by the learning algorithm according to the third packet feedback data;
wherein the third packet feedback data comprises one of a permitted packet feedback message and an error packet feedback message.

14. The signal correction method as claimed in claim 13, further comprising:
obtaining first slope data according to the first slice waveform signal and the second slice waveform signal; and
updating the learning algorithm according to the first slope data;
wherein the first slope data is associated to the first wavelength width and the second wavelength width.

15. The signal correction method as claimed in claim 13, further comprising:
obtaining first slice count data and second slice count data respectively according to the first slice waveform signal and the second slice waveform signal;
constructing a third data trend line according to a plurality of ground signals and a plurality of slice count data; and
updating the learning algorithm according to the third data trend line;
wherein the plurality of slice count data comprises the first slice waveform signal and the second slice waveform signal;
wherein the plurality of ground signals is associated to a voltage level of a ground line.
